(19) United States
(12) Patent Application Publication
(10) Pub. No.: US 2006/0186481 A1
(43) Pub. Date: Aug. 24, 2006

(54) NON-VOLATILE MEMORY AND MANUFACTURING METHOD AND OPERATING METHOD THEREOF

(76) Inventors: Ching-Sung Yang, Hsinchu City (TW); Wei-Zhe Wong, Tainan City (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/161,312

(22) Filed: Jul. 29, 2005

(30) Foreign Application Priority Data
Feb. 23, 2005 (TW) 94105352

(51) Int. Cl. H01L 29/76

(52) U.S. Cl. 257/371

(57) ABSTRACT

A non-volatile memory having many memory cell columns is provided. Each memory cell column includes a plurality of memory cells formed on a substrate. A deep p-type well is disposed in the substrate and an n-type well is disposed on the deep p-type well. A shallow p-type well isolated by device isolation structures is disposed on the n-type well. A select unit is disposed on one side of each memory cell column. An n-type source region is disposed in the substrate adjacent to the select unit. An n-type drain region is disposed in the substrate on the other side of the memory cell column. A bit line is disposed on the substrate. The bit line connects with the n-type drain region through a conductive plug. The conductive plug penetrates the junction between the n-type drain region and the shallow p-type well and forms a short between them.

### CROSS-REFERENCE TO RELATED APPLICATION

This application claims the priority benefit of Taiwan application serial no. 94105352, filed on Feb. 23, 2005. All disclosure of the Taiwan application is incorporated herein by reference.

### BACKGROUND OF THE INVENTION

1. Field of the Invention

The present invention relates to a semiconductor memory device. More particularly, the present invention relates to a non-volatile memory and a manufacturing method and operating method thereof.

2. Description of the Related Art

Among the various types of non-volatile memory products, electrically erasable programmable read only memory (EEPROM) is a memory device that has been widely used inside personal computer systems and electron equipment. In an EEPROM, data can be stored, read out or erased numerous times and any stored data can be retained even after power is cut off.

Typically, a floating gate and control gate of an EEPROM cell are fabricated using doped polysilicon. To prevent errors in reading data from an EEPROM due to over-erasing, an additional select gate is set up on the sidewall of the control gate and the floating gate above the substrate to form a split-gate structure.

In the conventional technique, a charge-trapping layer sometimes replaces the polysilicon floating gate. The charge-trapping layer is fabricated using silicon nitride, for example. In general, an oxide layer is formed both above and below the silicon nitride charge-trapping layer respectively to form a stacked structure including an oxide-nitride-oxide (ONO) composite layer. This type of memory is often referred to as a silicon-oxide-nitride-oxide-silicon (SONOS) memory device. A SONOS device having a split-gate structure has been disclosed, for example, in U.S. Pat. No. 5,930,631.

However, the aforementioned SONOS device with split-gate structures needs to have a larger area for accommodating the split-gate structures. With an increase in the dimension of each memory cell, the SONOS memory occupies an area larger than the conventional EEPROM with stacked gate structures and hence has a lower level of device integration.

### SUMMARY OF THE INVENTION

Accordingly, at least one objective of the present invention is to provide a non-volatile memory and an operating method thereof that can increase the level of integration of memory cells and the performance of the devices.

At least a second objective of the present invention is to provide a non-volatile memory and an operating method thereof that utilizes FN (Fowler-Nordheim) tunneling to perform data programming and erasing operations. Hence, programming speed is increased and memory performance is improved.

At least a third objective of the present invention is to provide a non-volatile memory and an operating method thereof that can stabilize memory cell programming and reading operation and increase programming efficiency.

To achieve these and other advantages and in accordance with the purpose of the invention, as embodied and broadly described herein, the invention provides a non-volatile memory. The non-volatile memory mainly includes a substrate, a second conductive type first well, a first conductive type second well, a plurality of second conductive type third wells, a plurality of bit lines, a plurality of word lines, a plurality of memory cell columns, a select unit, a first conductive type first doped region and a first conductive type second doped region. The substrate has device isolation structures formed thereon to define active regions. The second conductive type first well is disposed in the substrate. The first conductive type second well is disposed on the second conductive type first well. The second conductive type third wells are disposed on the first conductive type second well. Furthermore, the second conductive type third well is isolated from each other by the device isolation structures. The bit lines are disposed on the substrate. The word lines are disposed on the substrate such that the word lines and the bit lines cross over each other. The crossing points between the word lines and each bit line corresponds to a memory cell column. Each memory cell column includes a plurality of first memory cells and a plurality of second memory cells. The select unit is disposed on one side of the memory cell column. The plurality of first memory cells and select unit are separated from one another by a gap respectively. The second memory cells are disposed in the gaps through a plurality of spacers respectively. The first conductive type first doped region is disposed in the substrate on the outer side of the select unit. The first conductive type drain region is disposed in the substrate on another outer side of the memory cell column. The first conductive type second doped region and the second conductive type third well are electrically shorted together and electrically connected to a corresponding one of the bit lines.

In the aforementioned non-volatile memory, the first doped region is source region and the second doped is drain region. Each first memory cell includes a first charge-trapping layer and a first gate sequentially deposed on the substrate. Similarly, each second memory cell includes a second charge-trapping layer and a second gate sequentially formed on the substrate.

In the aforementioned non-volatile memory, each memory cell further includes a first bottom dielectric layer disposed between the first charge-trapping layer and the substrate and a top dielectric layer disposed between the first charge-trapping layer and the first gate. Furthermore, each second memory cell includes a second bottom dielectric layer disposed between the second charge-trapping layer and the substrate and a second top dielectric layer disposed between the second charge-trapping layer and the second gate. The select unit includes a third bottom dielectric layer, a third charge-trapping layer, a third top dielectric layer and a third gate sequentially formed on the substrate.

In the aforementioned non-volatile memory, the first charge-trapping layer, the second charge-trapping layer, the third charge-trapping layer are fabricated using silicon nitride or doped polysilicon. The first bottom dielectric layer, the first top dielectric layer, the second bottom dielectric layer, the second top dielectric layer, the third bottom dielectric layer and the third top dielectric layer are fabricated using silicon oxide.

In the aforementioned non-volatile memory, the first conductive type is n-type and the second conductive type is p-type.

In the aforementioned non-volatile memory, the memory further includes an interlayer insulating layer and a plurality of conductive plugs. The inter-layer insulating layer is disposed on the substrate. The conductive plugs are disposed in the inter-layer insulating layer. Each conductive plug connects the first conductive type drain region to a corresponding bit line.

In the aforementioned memory, the memory further includes a plurality of spacers. The spacers are disposed on the sidewalls of the first memory cells and the select unit respectively.

The present invention also provides an alternative non-volatile memory. The non-volatile memory mainly includes a substrate, a second conductive type first well, a first conductive type second well, a plurality of second conductive type third wells, a plurality of memory cell columns, a plurality of select lines, a plurality of word lines, a plurality of source lines and a plurality of bit lines. The substrate has device isolation structures formed thereon to define active regions. The second conductive type first well is disposed in the substrate. The first conductive type second well is disposed on the second conductive type first well. The second conductive type third wells are disposed on the first conductive type second well. Furthermore, the second conductive type third wells are isolated from each other by the device isolation structures. The memory cell columns are arranged to form an array disposed respectively on the second conductive third well of the first conductive substrate. Each memory cell column includes a plurality of memory cells, a select unit, a first conductive type source region and a first conductive type drain region. The memory cells are isolated from each other by a first insulating spacer but serially connected to together. The select unit is connected to one of the outermost memory cells of the serially connected memory cells through a second insulating spacer. The first conductive type source region is disposed in the substrate on the outer side of the select unit. The first conductive type drain region is disposed in the substrate on the other side of the serially connected memory cells. The select lines connect gates of the select units in the same row respectively. The word lines are arranged in parallel in the row direction and connect to gates of the memory cells in the same row respectively. The source lines connect the first conductive type source regions in the same row. The bit lines are arranged in parallel in the column direction and connect the first conductive type drain regions in the same column through conductive plugs. The conductive plugs penetrate through the junctions between the first conductive type drain region and the second conductive type third well respectively so that the first conductive type drain region and the second conductive type third well are electrically shorted together.

In the aforementioned non-volatile memory, for the memory cells in the same memory cell column, every pair of adjacent memory cells starting from the first conductive type drain region side constitutes a a plurality of memory units. The memory cell near to the first conductive type drain region is a first memory cell and the memory cell near to the first conductive type source region is a second memory cell. The first memory cell includes a first gate disposed on the substrate and a first composite layer disposed between the first gate and the substrate. The composite layer includes a first bottom dielectric layer, a first charge-trapping layer and a top dielectric layer sequentially formed on the substrate. The second memory cell is disposed on the sidewall on one side of the first memory cell and the substrate. The second memory cell includes a second gate disposed on the substrate and a second composite layer disposed between the second gate and the substrate and the second gate and the first memory cell. The second composite layer includes a second bottom dielectric layer, a second charge-trapping layer and a second top dielectric layer sequentially formed on the substrate and the sidewall on one side of the first memory cell. The first insulating spacers are disposed on the sidewalls of the first memory cells.

In the aforementioned non-volatile memory, for the memory cells in the same memory cell column, every pair of adjacent memory cells from the first conductive type drain region side to the first conductive type source region side constitutes a memory unit. The memory cell close to the first conductive type drain region is named a first memory cell and the memory cell close to the first conductive type source region is named a second memory cell. The first memory cell includes a first gate disposed on the substrate and a first composite layer disposed between the first gate and the substrate. The composite layer includes a first bottom dielectric layer, a first charge-trapping layer and a first top dielectric layer sequentially formed on the substrate. The second memory includes a second gate disposed on the substrate and a second composite layer disposed between the second gate and the substrate and between the second gate and the first memory cell. The second composite layer includes a second bottom dielectric layer, a second charge-trapping layer and a second top dielectric layer sequentially formed on the sidewall on one side of the substrate and the first memory cell. The first insulating spacers are disposed on the sidewall of the first memory cells.

In the aforementioned non-volatile memory, the first charge-trapping layer and the second charge-trapping layer is fabricated using silicon nitride or doped polysilicon. The first bottom dielectric layer, the first top dielectric layer, the second bottom dielectric layer and the second top dielectric layer are fabricated using silicon oxide. The select unit includes a third gate disposed on the substrate and a third composite layer disposed between the third gate and the substrate. The third composite layer includes a third bottom dielectric layer, a third charge-trapping layer and a third top dielectric layer sequentially formed on the substrate. Third insulating spacers are disposed on the sidewall of the third gate and the third composite layer.

In the aforementioned non-volatile memory, the third charge-trapping layer is fabricated using silicon nitride or doped polysilicon. The third bottom dielectric layer and the third to dielectric layer are fabricated using silicon oxide.

In the aforementioned non-volatile memory, the memory cell columns on the active region includes a plurality of alternately laid first memory cells and second memory cells and select units. Since there is no gap between the first memory cell and the second memory cell and there is no gap between the select unit and the second memory cell, overall level of integration of the memory cell array is increased.

Furthermore, because the first memory cell and the second memory cell both use the charge-trapping layer as a charge storage unit, there is no need to consider gate coupling ratio. Hence, the required operating voltage can be reduced and the operating efficiency of the memory cell can be increased. Moreover, each first memory cell and each second memory cell in a memory cell column is able to store electric charges. Thus, storage capacity of the non-volatile memory can be significantly increased.

In the present invention, the first conductive type drain region and the second conductive type third well are short-circuited together to facilitate the reading of data from the non-volatile memory device. Therefore, the read-out speed is increased and the performance of the device is improved. In addition, the non-volatile memory of the present invention utilizes FN tunneling effect to carry out programming and erasing operation. Thus, memory cell current can be reduced and the operating speed can be increased. Moreover, when programming and erasing is triggered by FN tunneling, current waste is minimized and power loss from the chip is effectively reduced.

The present invention also provides a method of operating a non-volatile memory, in particular, for operating a memory cell array. To carry out an erasing operation, a first voltage is applied to the word line; a second voltage is applied to the source line and the second conductive type third well; a third voltage is applied to the select line, the first conductive type second well and the second conductive type first well; and, the bit line is set to a floating state. The voltage differential between the first voltage and the second voltage is sufficiently high so that electrons are injected into the charge-trapping layer by FN tunneling to erase the data in the entire memory cell array.

In the aforementioned method of operating the non-volatile memory, the first voltage is about 6V, the second voltage is about −6V and the third voltage is about 0V.

To carry out a programming operation in the aforementioned method of operating the non-volatile memory, a fourth voltage is applied to a selected bit line; a fifth voltage is applied to a selected source line; a sixth voltage is applied to the word line that couples with the selected memory cell and a seventh voltage is applied to the word lines that couple with the non-selected memory cells and the select line; and an eighth voltage is applied to the first conductive type second well. The voltage differential between the fourth voltage and the sixth voltage is sufficiently to pull electrons out of the charge-trapping layer by FN tunneling in the process of programming the selected memory cell.

In the aforementioned method of operating the non-volatile memory, the fourth voltage is about 3.3V, the fifth voltage is about 3.3V, the sixth voltage is about −9V, the seventh voltage is about 0V and the eighth voltage is about 3.3V.

To read data in the aforementioned method of operating the non-volatile memory, a 0V is applied to the selected bit line; a ninth voltage is applied to the word line that couples to the selected memory cell and a tenth voltage is applied to other non-selected word lines and corresponding select lines; and, an eleventh voltage is applied to the source line. The tenth voltage is high enough to turn on the channel between the memory cell and the select unit and the ninth voltage is lower than the threshold voltage of the memory cell in the erase state but higher than the threshold voltage of the memory cell in the programming state for reading data from the selected memory cell.

In the aforementioned method of operating the non-volatile memory, the ninth voltage is about 1.5V, the tenth voltage is about 6V and the eleventh voltage is about 1.5V.

In the method of operating a non-volatile memory according to the present invention, the programming of each memory cell in a memory cell column includes directly setting up a voltage differential between the gate and the substrate. Therefore, electrons are pulled from the charge-trapping layer of the memory cell into the substrate or holes are injected into the charge-trapping layer so that the threshold voltage of the memory cell is reduced and FN tunneling effect is used to program the memory cell. Hence, programming interference caused by a different threshold voltage in other memory cells of the same memory cell column can be avoided. Ultimately, programming efficiency is improved.

In the method of operating a non-volatile memory according to the present invention, FN tunneling is used for carrying out programming and erasing operation. Thus, the memory cell current can be reduced and the operating speed can be increased. Furthermore, because both programming and erasing operation are carried out using FN tunneling, current consumption is low so that power loss from the entire chip is effectively reduced. In addition, the first conductive type drain region and the second conductive type third well are short-circuited together to facilitate reading from the non-volatile memory device. Consequently, the read-out rate is increased and the electrical performance of the device is improved.

The present invention also provides a method of fabricating a non-volatile memory. First, a substrate is provided. The substrate has device isolation structures thereon to define an active region. Then, a second conductive type first well is formed in the substrate. Thereafter, a first conductive type second well is formed in the second conductive type first well and then a plurality of second conductive type third wells are formed on the first conductive type second well such that the second conductive type third well is isolated from each other by the device isolation structures. Afterwards, a plurality of stacked gate structures is formed on the substrate. Each stacked gate structure includes a first composite layer, a first gate and a cap layer. Furthermore, there is a gap between the stacked gate structures in every pair of adjacent stacked gate structures. After forming a plurality of insulating spacers on the sidewalls of the stacked gate structures, a second composite layer is formed over the substrate. Then, a conductive layer is formed over the substrate. A portion of the conductive layer is removed to form a plurality of second gates that fills the gaps between the stacked gate structures respectively. The second gates and the stacked gate structures together form a memory cell column. After that, a first conductive type source region and a first conductive type drain region are formed on the sides of the memory cell column respectively. After forming a first inter-layer insulating layer over the substrate, a source line is formed in the first inter-layer insulating layer. The source line connects with the first conductive type source region. After forming a second inter-layer insulating layer over the first inter-layer insulating layer, a conductive lug is formed in the second inter-layer insulating layer. The conductive plug penetrates through the junction between the first conductive type drain region and the second conductive type third well so that the first conductive type drain region and the second conductive type third well are short-circuited together. After that, a bit line is formed on the second inter-layer insulating layer. The bit line connects with the conductive plug.

In the aforementioned method of fabricating the non-volatile memory, each of the first composite layer and the second composite layer includes a bottom dielectric layer, a charge-trapping layer and a top dielectric layer.

In the aforementioned method of fabricating the non-volatile memory, the method of removing a portion of the conductive layer includes performing a chemical-mechanical polishing operation. The method of forming the first conductive type source region and the first conductive type drain region in the substrate includes performing an ion implant process.

In the aforementioned method of fabricating the non-volatile memory, the step of forming insulating spacers on the sidewalls of the stacked gate structures includes depositing insulating material over the substrate and then performing a self-aligned anisotropic etching operation to remove a portion of the insulating layer.

In the aforementioned method of fabricating the non-volatile memory, the step of forming the conductive plug short-circuiting the first conductive type drain region and the second conductive type third well together facilitates the reading of data from the non-volatile memory. Hence, the read-out rate is increased and the electrical performance of the device is improved. Furthermore, the second conductive type third well is isolated by the device isolation structures to form an isolated well. Through this isolated well, FN tunneling can be used to perform a programming or an erasing operation. Hence, the memory cell current can be reduced and the operating speed can be increased. Moreover, when programming and erasing operation action are triggered through FN tunneling, current consumption is minimized and power loss from the entire chip is effectively reduced.

In addition, with another gate structure produced in the gap between a pair of neighboring stacked gate structures by forming a second composite layer and a second gate, there no need to perform another photolithographic and etching process. Hence, the fabrication process is very much simplified and overall production cost is reduced. Furthermore, the charge-trapping layer serves as a charge storage unit in the non-volatile memory of the present invention. Thus, there is no need to consider gate-coupling ratio. Consequently, the required voltage for operating the memory can be reduced and overall operating efficiency of the memory cell can be increased. Moreover, the steps for fabricating the non-volatile memory in the present invention are simpler than the conventional process. Thus, overall production cost of the non-volatile memory is reduced.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a top view of a non-volatile memory according to the present invention.

FIG. 1B is a cross-sectional view along line A-A′ of FIG. 1A showing the structure of a non-volatile memory.

FIG. 1C is a cross-sectional view showing the structure of a memory unit and a select unit according to the present invention.

FIG. 1D is a cross-sectional view along line B-B′ of FIG. 1A showing the structure of a non-volatile memory.

FIG. 2 is a simplified circuit diagram of a non-volatile memory according to the present invention for showing the operating mode of the non-volatile memory.

FIG. 3A is a schematic cross-sectional view of a non-volatile memory for showing a programming operation according to the present invention.

FIG. 3B is a schematic cross-sectional view of a non-volatile memory for showing a reading operation according to the present invention.

FIG. 3C is a schematic cross-sectional view of a non-volatile memory for showing an erasing operation according to the present invention.

FIGS. 4A through 4E are schematic cross-sectional views showing the steps for fabricating a non-volatile memory according to the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

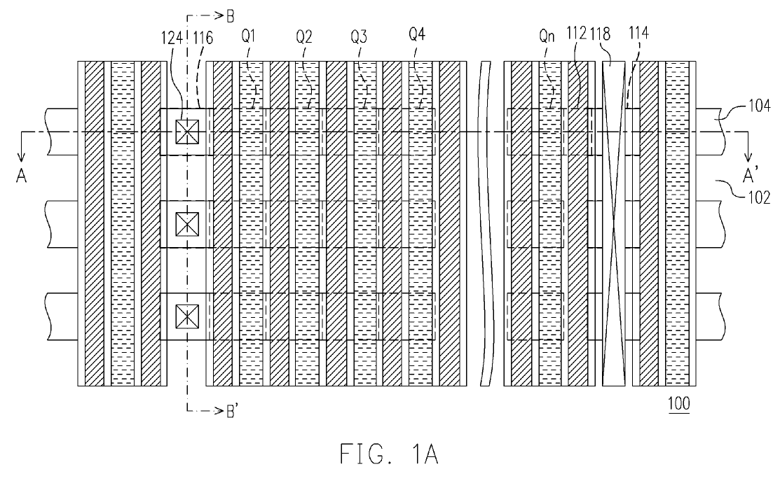

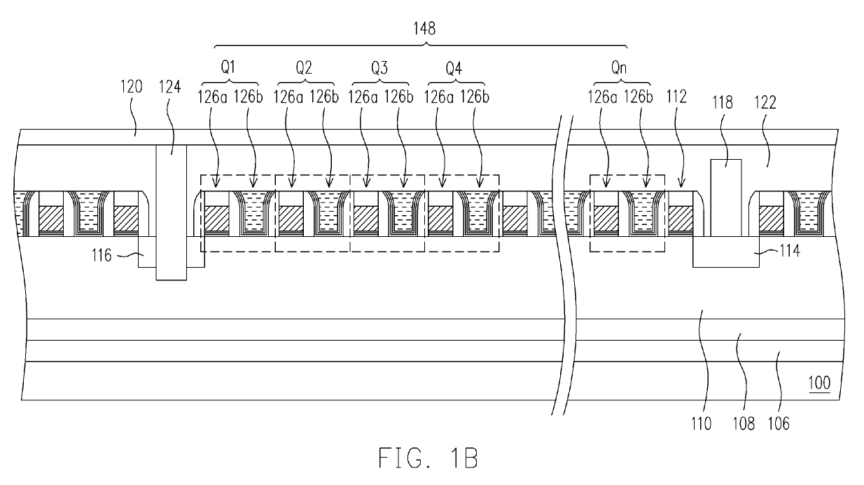

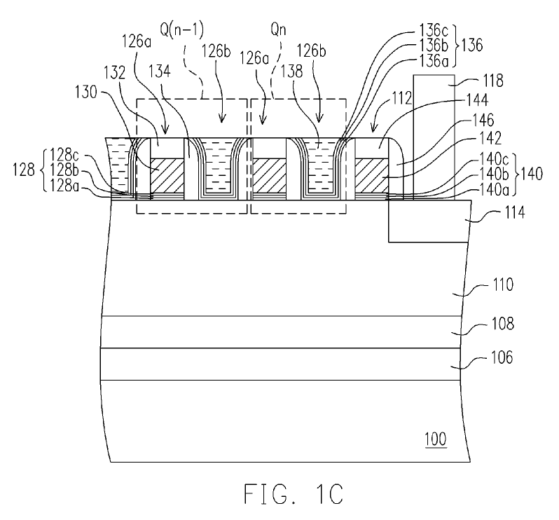

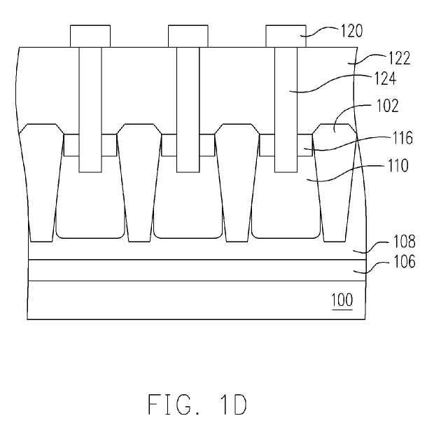

FIG. 1A is a top view of a non-volatile memory according to the present invention. FIG. 1B is a cross-sectional view along line A-A′ of FIG. 1A showing the structure of a non-volatile memory. FIG. 1C is a cross-sectional view showing the structure of a memory unit and a select unit according to the present invention. FIG. 1D is a cross-sectional view along line B-B′ of FIG. 1A showing the structure of a non-volatile memory.

As shown in FIGS. 1A, 1B, 1C and 1D, the non-volatile memory structure according to the present invention includes at least a substrate 100, a device isolation structure 102, an active region 104, a deep p-type well 106, an n-type well 108, a p-type well 110, a plurality of memory units Q1˜Qn, a select unit 112, an n-type source region 114, an n-type drain region 116, a source line 118, a bit line 120, an inter-layer insulating layer 122 and a conductive plug 124.

The substrate 100 is a silicon substrate such as an n-type substrate, for example. The device isolation structure 102 is disposed in the substrate 100 for defining an active region 104. The deep p-type well 106 is disposed in the substrate 100. The n-type well 108 is disposed in the deep p-type well 106. The p-type well 110 is disposed in the n-type well 108 and isolated through the device isolation structure 102.

The memory units Q1˜Qn are disposed on the substrate 100. Each of the memory units Q1˜Qn includes a memory cell 126a and a memory cell 126b.

The memory cell 126a is disposed on the substrate 100. The memory cell 126a includes a composite layer 128, a gate 130, a cap layer 132 and an insulating spacer 134, for example. The gate 130 is disposed on the substrate 100. The composite layer 128 includes a bottom dielectric layer 128a, a charge-trapping layer 128b and a top dielectric layer 128c sequentially formed on the substrate 100. The cap layer 132 is disposed on the gate 130. The insulating spacer 134 is disposed on the sidewall of the gate 130 and the composite layer 128. The insulating spacer 134 is formed, for example, by depositing insulating material over the gate 130 and performing a self-aligned anisotropic etching operation. The bottom dielectric layer 128a is fabricated using silicon oxide, the charge-trapping layer 128b is fabricated using silicon nitride or doped polysilicon, the top dielectric layer 128c is fabricated using silicon oxide and the gate 130 is fabricated using doped polysilicon, for example. The cap layer 132 is fabricated using silicon oxide, for example. The insulating spacer 134 is fabricated using an insulating material such as silicon nitride or silicon oxide.

The memory cell 126b is disposed on the sidewall of the memory cell 126a and the substrate 100. The memory cell 126b includes a composite layer 136 and a gate 138, for example. The gate 138 is disposed on the substrate 100 and the composite layer 136 is disposed between the gate 138 and the substrate 100 and between the gate 138 and the memory cell 126a. The composite layer 136 includes a bottom dielectric layer 136a, a charge-trapping layer 136b and a top dielectric layer 136c sequentially formed on the substrate 100 and the sidewall of the memory cell 126a. The bottom dielectric layer 136a is fabricated using silicon oxide, the charge-trapping layer 136b is fabricated using silicon nitride, the top dielectric layer 136c is fabricated using silicon oxide and the gate 138 is fabricated using doped polysilicon, for example. The memory cell 126b is isolated from the memory cell 126a through the insulating spacer 134.

The memory units Q1˜Qn are serially connected on the active region 104. Furthermore, the memory cells 126a and the memory cells 126b are alternately laid without any gaps between them. Each memory cell 126a is isolated from a neighboring memory cell 126b through an insulating spacer 134.

The select unit 112 is connected to the outermost memory cell 126b of the serially connected memory units Q1˜Qn. The select unit 112 includes a composite layer 140, a gate 142, a cap layer 144 and an insulating spacer 146, for example. The gate 142 is disposed on the substrate 100. The composite layer 140 is disposed between the gate 142 and the substrate 100. The composite layer 140 includes a bottom dielectric layer 140a, a charge-trapping layer 140b and a top dielectric layer 140c sequentially formed on the substrate 100. The cap layer 144 is disposed on the gate 142. The insulating spacer 146 is disposed on the sidewall of the gate 142 and the composite layer 140. The bottom dielectric layer 140a is fabricated using silicon oxide, the charge-trapping layer 140b is fabricated using silicon nitride or doped polysilicon, the top dielectric layer 140c is fabricated using silicon oxide and the gate 142 is fabricated using doped polysilicon, for example. The cap layer 144 is fabricated using silicon oxide, for example. The insulating spacer 146 is fabricated using silicon nitride or silicon oxide, for example. The select unit 112 is isolated from the outermost memory cell 126b of the serially connected memory units Q1˜Qn through the insulating spacer 146.

The source region 114 is disposed in the substrate 100 on that side of the select unit 112 not adjacent to the serially connected memory units Q1˜Qn, for example. The drain region 116 is disposed in the substrate 100 on the other side of the source region 114. That is, the drain region 116 is disposed in the substrate 100 on one side of the outermost memory cell 126a of the serially connected memory units Q1˜Qn. Both the source region 114 and the drain region 116 are n-doped regions, for example.

The inter-layer insulating layer 122 is disposed on the substrate 100. The inter-layer insulating layer 122 is fabricated using silicon oxide, for example. The bit line 120 is disposed on the inter-layer insulating layer 122. The source line 118 and the conductive plug 124 are disposed in the inter-layer insulating layer 122. The source region 114 is electrically connected to the source line 118. The drain region 116 is electrically connected to the bit line 120 through the conductive plug 124. The conductive plug 124 penetrates through the junction between the drain region 116 and the p-type well 110 so that the drain region 116 and the p-type well 110 are short-circuited together.

In the aforementioned non-volatile memory, the memory cell column 148 on the active region 104 includes a plurality of alternately laid memory cells 126a and memory cells 126b. Because no gaps exist between each memory cell 126a and a neighboring memory cell 126b and no gaps exist between the select unit 112 and an adjacent memory cell 126b, the level of integration of the memory cell array can be increased.

Furthermore, the memory cells 126a and the memory cells 126b use the charge-trapping layer 110 as a charge storage unit. Thus, there is no need to consider the gate-coupling ratio. As a result, the required voltage for operating the memory can be reduced and the operating efficiency of the memory cells can be increased. Moreover, each and every one of the memory cells 126a and the memory cells 126b in the memory cell column 148 can be used for storing electric charges. Consequently, overall storage capacity of the memory is also increased.

In addition, the p-type well 110 and the drain region 124 are short-circuited together in the present invention to facilitate the reading of data from the non-volatile memory. Therefore, the data read-out speed can be increased and the performance of the device can be improved. Furthermore, the non-volatile memory uses FN tunneling effect to perform programming and erasing operation so that the memory cell current can be reduced and the operating speed of the device can be increased. Moreover, with both the programming and erasing operation effected through FN tunneling, the current consumption is minimized and the power loss from the entire chip is reduced.

Additionally, the number of memory cells serially connected together may vary according to the actual requirement. For example, a total of between 32 to 64 of memory cell structures may be serially connected to the same memory cell column 148.

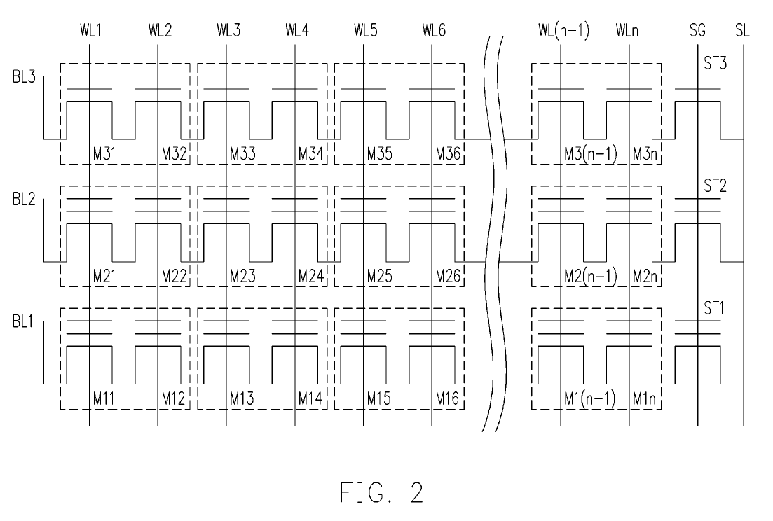

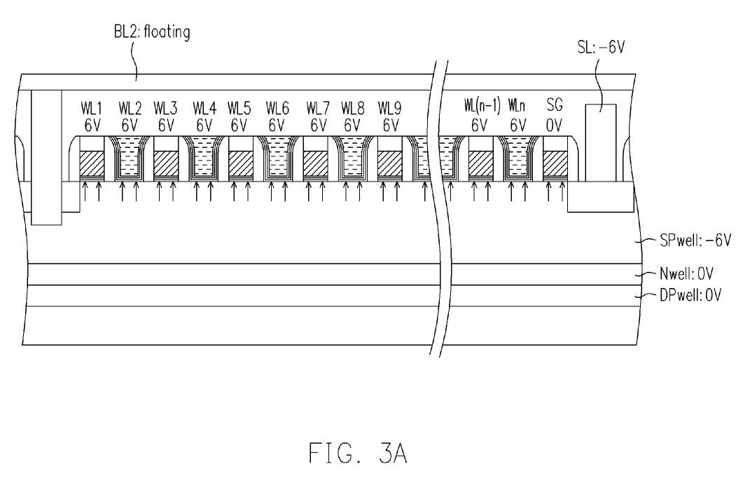

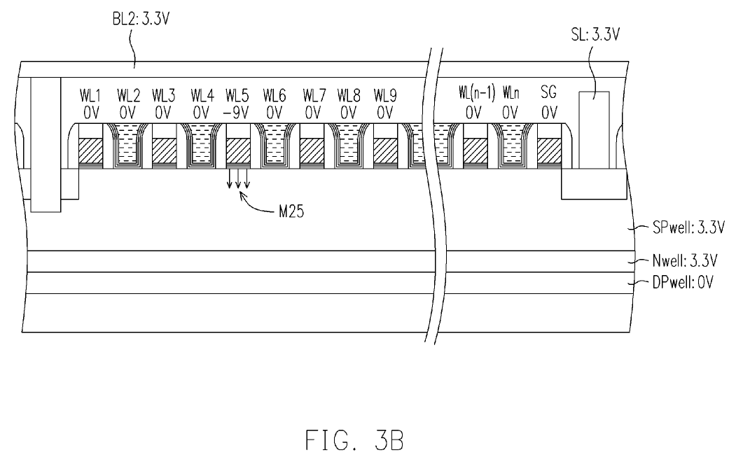

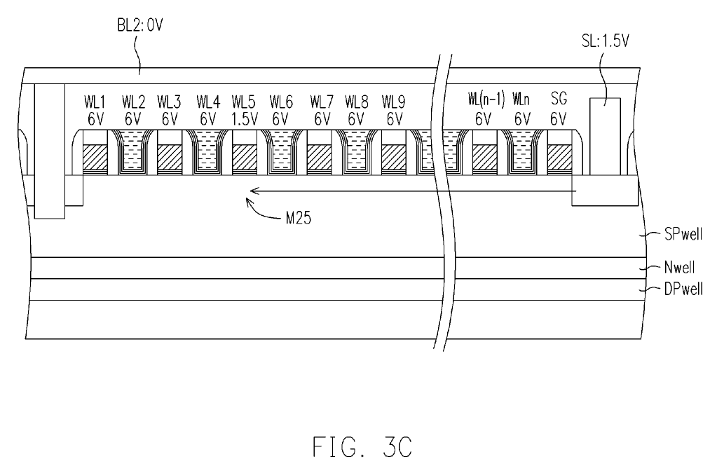

FIG. 2 is a simplified circuit diagram of a non-volatile memory according to the present invention for showing the operating mode of the non-volatile memory. FIG. 3A is a schematic cross-sectional view of a non-volatile memory for showing a programming operation according to the present invention. FIG. 3B is a schematic cross-sectional view of a non-volatile memory for showing a reading operation according to the present invention. FIG. 3C is a schematic cross-sectional view of a non-volatile memory for showing an erasing operation according to the present invention.

As shown in FIG. 2, the non-volatile memory includes a plurality of memory cells M11˜M3n, a plurality of select units ST1˜ST3, a select line SG, a plurality of word lines WL1˜WLn, a plurality of bit lines BL1˜BL3 and a source line SL.

The memory cells M11˜M3n are disposed on the substrate and arranged to form a column/row array. The memory cells in the same column are serially connected without any gaps in-between to form a memory cell column. For example, the memory cells M21, M22, M13 . . . M2n together form a memory cell column and the memory cells M31, M32, M33 . . . M3n together form another memory cell column.

The select units ST1˜ST3 are connected to the outermost memory cell of memory cell columns, respectively. For example, the select unit ST1 connects with the memory cell M1n; the select unit ST2 connects with the memory cell M2n; and, the select gate ST3 connects with the memory cell M3n. The select line SG connects with the gate of the select units ST1˜ST3 in the same row. The word lines WL1˜WLn are arranged in parallel in the row direction and connect with the gate of memory cells in the same row. For example, the word line WL1 connects with the gate of the memory cell M11, M21 and M31; the word line WL2 connects with the gate of the memory cell M13, M23 and M33; and so on; and, the word line WLn connects with the gate of the memory cell M1n, M2n and M3n. The source line SL connects with the source regions in the same row. The source regions are disposed in the substrate on one side of the select units ST1˜ST3 respectively. The bit lines BL1˜BL3 are arranged in parallel in the column direction and connect with to the drain regions in the same column. The drain regions are disposed in the substrate on another side of the memory cell columns respectively. In each memory cell column, every pair of adjacent memory cells forms a memory unit Q. For example, the memory cells M11 and M12 form a memory unit; the memory cells M13 and M14 form another memory unit; and so on, and the memory cells M3(n−1) and M3n form yet another memory unit. As shown in FIGS. 3A˜3C, the n-type substrate has a deep p-type well DPwell. The deep p-type well DPwell in the n-type substrate has an n-type well Nwell. The n-type well Nwell in the n-type substrate has a shallow p-type well SPwell. The shallow p-type well SPwell is isolated through a device isolation structure (not shown).

To carry out an erasing operation, as shown in FIGS. 2 and 3A, a voltage of about 6V is applied to all word lines; a voltage of about 6V is applied to the source line SL so that the shallow p-type well SPwell also has a voltage of about 6V; a voltage of about 0V is applied to the select line; the bit lines BL1˜BL3 are set to a floating state; and, a voltage of about 0V is applied to the n-type well Nwell and the deep p-type well DPwell. The voltage differential between the word lines and the source line SL is sufficient to trigger FN tunneling effect so that electrons are injected into the charge-trapping layer to increase the threshold voltage of the memory cells, thereby erasing the data from the entire memory cell array.

To program data into the memory cell M25, for example, as shown in FIGS. 2 and 3B, a voltage of about 3.3V is applied to the select bit line BL2 so that the shallow p-type well SPwell also has a voltage of about 3.3V; a voltage of about 3.3V is applied to the selected source line; a voltage of about 9V is applied to the word line WL5 that couples with the select memory cell M25 and a voltage of about 0V is applied to the select line SG and the word lines WL1˜WL4 and WL6˜WLn that couple with other non-selected memory cells; and, a voltage of about 3.3V is applied to the n-type well Nwell. The voltage differential between the selected bit line BL2 and the word lines WL5 that couples with the selected memory cell M25 is sufficient to trigger FN tunneling so that electrons are pulled out from the charge-trapping layer or holes are injected into the charge-trapping layer. Consequently, the threshold voltage of the memory cell is reduced and data is programmed into the selected memory cell M25.

The other memory cells M21˜M24, M26˜M2n that use the same bit line BL2 as the memory cell M25 are not programmed because a 0V is applied to the word lines WL1˜WL4 and WL6˜WLn. The other memory cells M15, M35 that use the same word line WL5 as the memory cell M25 are also not programmed because a voltage of 3.3V is not applied to the bit lines BL1 and BL3. The other memory cells M11˜M14, M16˜M1n, M31˜M34, M36˜M3n that do not use the same bit line BL2 and the same word line WL5 as the memory cell M25 are also not programmed. This is because a 0V is applied to the word lines WL1˜WL4, WL6˜WLn and a 3.3V is not applied to the bit lines BL1 and BL3.

In the aforementioned programming method, when the various memory cells in the memory cell column are programmed, a voltage differential is directly set up between the gate and the substrate so that electrons can be pulled from the charge-trapping layer of the memory cell to the substrate or holes can be injected into the charge-trapping layer to reduce the threshold voltage of the memory cell and utilize FN tunneling to program the memory cell. Therefore, programming interference due to a difference in threshold voltage in the other memory cells of the same memory cell column can be avoided so that the programming efficiency is increased.

To read data from a memory cell M25, for example, as shown in FIGS. 2 and 3C, a voltage of about 0V is applied to the selected bit line BL2 and a voltage of about 1.5V is applied to the non-selected bit lines BL1, BL3; a voltage of about 1.5V is applied to the word line WL5 that couples with the selected memory cell M25 and a voltage of about 6V is applied to other non-selected word lines WL1˜WL4, WL6˜WLn and the select line SG; and, a voltage of about 1.5V is applied to the source line SL to read data from the selected memory cell M25. The voltage applied to other non-selected word lines WL1˜WL4, WL6˜WLn and select line SG must be high enough to open the channel of the memory cell and the select unit. The voltage applied to the source line SL must be lower than the threshold voltage of the memory cells in the erasing state but higher than the threshold voltage of the memory cells in the programming state. Because the channel is shut with very little current when the net charges inside the charge-trapping layer is negative and the channel is open with a large current when the net charges inside the charge-trapping layer is only slightly positive, the shut-open state/current size in the channel can be used to determine whether a digital data ‘1’ or ‘0’ is stored inside the memory cell.

The non-volatile memory of the present invention utilizes FN tunneling to perform programming and erasing operation. Hence, the memory cell current is reduced and the operating speed in increased. Furthermore, by utilizing FN tunneling in both programming and erasing operation, the current consumption is minimized and the power low from the entire chip is reduced. In addition, the short-circuiting of the p-type well and the drain region together in the present invention facilitates the read-out of data from the non-volatile memory device, thereby increasing the read-out rate and improving device performance.

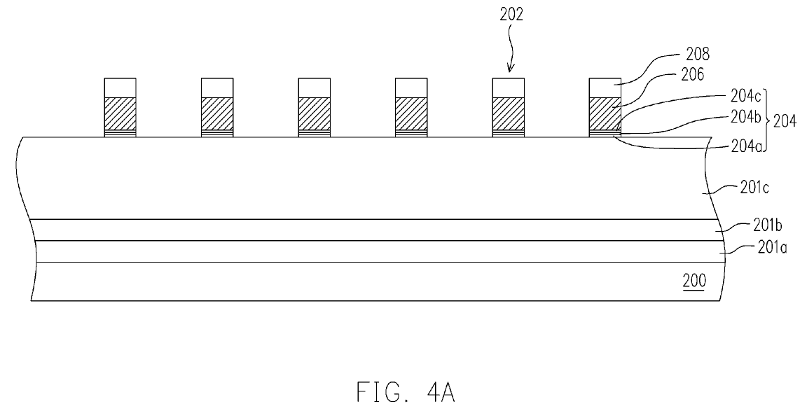

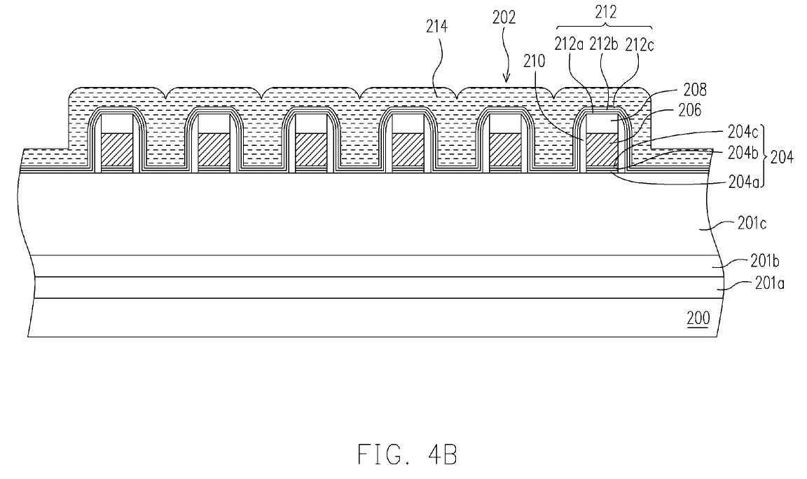

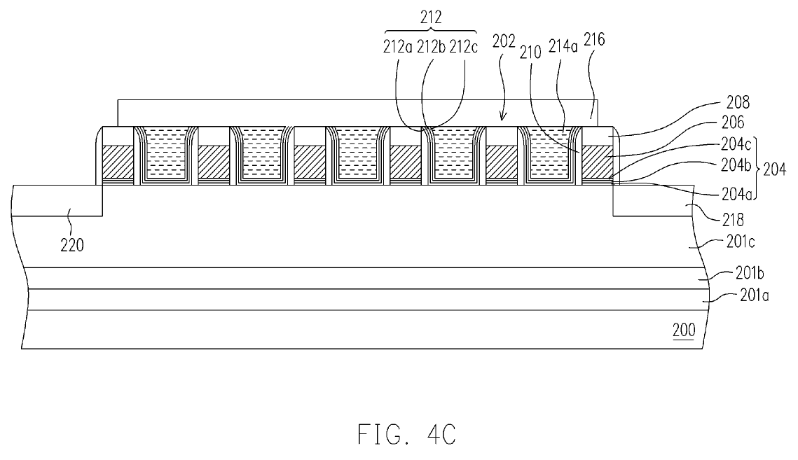

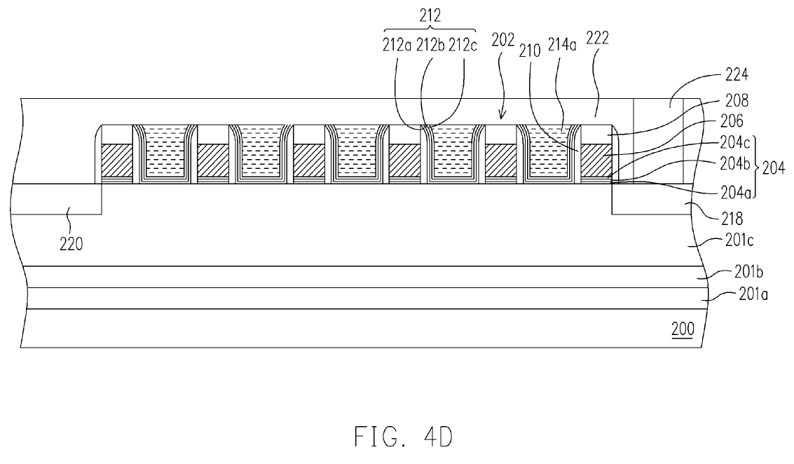

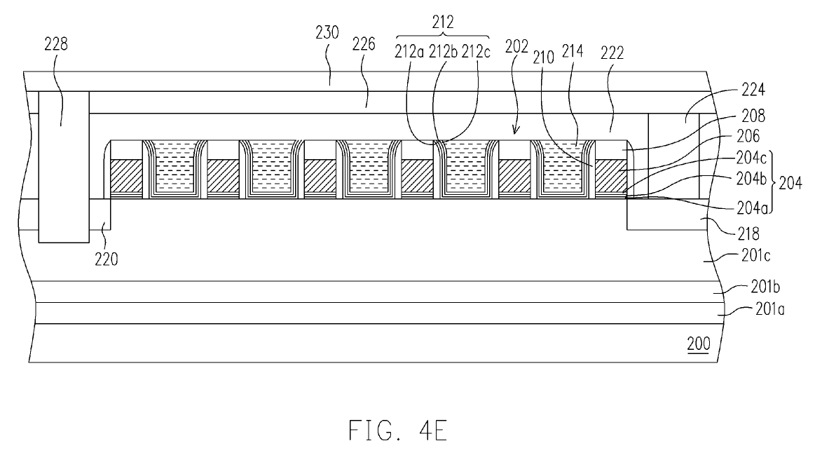

FIGS. 4A through 4E are schematic cross-sectional views showing the steps for fabricating a non-volatile memory according to the present invention. In fact, FIGS. 4A through 4E are cross-sectional views along line A-A′ of FIG. 1A. First, as shown in FIG. 4A, a substrate 200 such as a silicon substrate is provided. The substrate 200 can be an n-type substrate, for example. Furthermore, the substrate 200 has a device isolation structure (not shown) thereon that defines an active region. A deep p-type well 101a is formed in the substrate 100 and then an n-type well 101b is formed in the deep p-type well 101a. Thereafter, a p-type well 101c is formed in the n-type well 101b. The p-type well 101c is isolated through the device isolation structure.

Thereafter, stacked gate structures 202 are formed on the substrate 200. Each stacked gate structure 202 includes a composite layer 204, a conductive layer 206 (a gate) and a cap layer 208. The stacked gate structures 202 are formed, for example, by forming a composite dielectric material layer, a conductive material layer and an insulating material layer sequentially over the substrate 100 and patterning the aforementioned material layers using photolithographic and etching techniques.

The composite layer 204 further includes a bottom dielectric layer 204a, a charge-trapping layer 204 and a top dielectric layer 204c, for example. The bottom dielectric layer 204a is a silicon oxide layer formed by performing a thermal oxidation process, for example. The charge-trapping layer 204b is a silicon nitride layer formed by performing a chemical vapor deposition process, for example. The top dielectric layer 204c is a silicon oxide layer formed by performing a chemical vapor deposition process, for example. Obviously, the bottom dielectric layer 204a and the top dielectric layer 204c can be fabricated from other similar types of material. Similarly, the material constituting the charge-trapping layer 204b is not limited to silicon nitride. Other types of material that can trap electric charges, for example, tantalum oxide, titanium-strontium acid and hafnium oxide may also be used.

The conductive layer 206 is a doped polysilicon layer, for example. The conductive layer 206 is formed, for example, by depositing an undoped polysilicon layer over the substrate 200 in a chemical vapor deposition and performing an ion implanting process thereafter, or performing an in-situ ion implantation during the chemical vapor deposition.

The cap layer 208 is a silicon oxide layer, for example. The cap layer 208 is formed, for example, by performing a chemical vapor deposition process using tetra-ethyl-ortho-silicate (TEOS)/ozone (O3) as the reactive gases.

As shown in FIG. 4B, insulating spacers 210 are formed on the sidewalls of the stacked gate structures 202. The insulating spacers 210 are formed, for example, by depositing a layer of insulating material and performing a self-aligned anisotropic etching operation thereafter so that an insulating material layer is retained on the sidewalls of the stacked gate structures 202. The insulating spacers 210 are fabricated from silicon nitride, for example.

Thereafter, another composite layer 212 is formed over the substrate 200. The composite layer 212 includes a bottom dielectric layer 212a, a charge-trapping layer 212b and a top dielectric layer 212c. The bottom dielectric layer 212a is a silicon oxide layer formed, for example, by performing a thermal oxidation process. The charge-trapping layer 212b is a silicon nitride layer, for example, by performing a chemical vapor deposition process. The top dielectric layer 212c is a silicon oxide layer formed, for example, by performing a chemical vapor deposition process. Obviously, the bottom dielectric layer 212a and the top dielectric layer 212c can be fabricated from other similar types of material. Similarly, the material constituting the charge-trapping layer 212b is not limited to silicon nitride. Other types of material that can trap electric charges, for example, tantalum oxide, titanium-strontium acid and hafnium oxide may also be used.

After that, another conductive layer 124 is formed over the substrate 200. The conductive layer 214 completely fills the gap between two adjacent stacked gate structures 202. The conductive layer 214 is fabricated using doped polysilicon, for example. The conductive layer 214 is formed, for example, by depositing undoped polysilicon material to form an undoped polysilicon layer in a chemical vapor deposition and performing an ion implanting process thereafter, or performing an in-situ implanting process during the chemical vapor deposition.

As shown in FIG. 4C, a portion of the conductive layer 214 is removed until the cap layer 208 is exposed so that a conductive layer 214a (a gate) is formed between the adjacent stacked gate structures 202. The conductive layer 214a serially connects a plurality of stacked gate structures 202 together. The method of removing a portion of the conductive layer 214 includes performing an etching back process or a chemical-mechanical polishing operation. The conductive layer 214a and the composite layer 212 together constitute another gate structure. It should be noted that a silicide layer might be formed on the conductive layer 214a to decrease the resistance of the conductive layer 214a.

A patterned mask layer 216 is formed over the substrate 200 to expose the areas for forming the desired source/drain regions. Thereafter, an etching operation is carried out to remove any residual conductive layer 214 and composite layer 212 on top of the desired source/drain regions.

After that, using the mask layer 216 as a mask, a dopant implantation is carried out to form an n-type source region 218 and an n-type drain region 220 in the substrate 200. The n-type source region 218 and the n-type drain region 220 are located in the substrate 200 on the sides of the serially connected stacked gate structures 202 and conductive layer 214a respectively.

As shown in FIG. 4D, an inter-layer dielectric layer 222 is formed on the substrate 200. The inter-layer dielectric layer 222 is a silicon oxide layer formed, for example, by performing a chemical vapor deposition process. Thereafter, a source line 224 electrically connected to the n-type source region 218 is formed in the inter-layer dielectric layer 222. The source line 224 is fabricated using tungsten, for example.

As shown in FIG. 4E, another inter-layer dielectric layer 226 is formed over the substrate 200. Thereafter, a conductive plug 228 electrically connected to the n-type drain region 220 is formed in the inter-layer dielectric layer 226 and then a conductive line 230 (a bit line) electrically connected to the conductive plug 228 is formed on the inter-layer dielectric layer 226. The conductive plug 228 penetrates through the junction between the n-type drain region 220 and the p-type well 101c so that the two are short-circuited together. After that, other steps needed to complete the fabrication of the non-volatile memory are carried out. Since these steps should be familiar to those skilled in the techniques, a detailed description is omitted.

In the aforementioned embodiment, the p-type well 101c and the n-type drain region 220 are short-circuited together to facilitate the reading of data from the non-volatile memory. Hence, the read-out rate is increased and the performance of the device is improved. Furthermore, the p-type well 101c is isolated to form an isolated well by the device isolation structure. Through the isolation of the well, FN tunneling can be used to perform programming and erasing operation. Thus, the memory cell current is reduced and the operating speed of the non-volatile memory is increased. Moreover, with both the programming and erasing operation triggered by FN tunneling, current waste is minimized and power loss from the chip is effectively reduced.

In addition, with another gate structure produced in the gap between a pair of neighboring stacked gate structures 202 by forming the composite layer 212 and the conductive layer 214a, there no need to perform another photolithographic and etching process. Hence, the fabrication process is very much simplified and overall production cost is reduced. Furthermore, the charge-trapping layers 204b and 212b serve as charge storage units in the non-volatile memory of the present invention. Thus, there is no need to consider gate-coupling ratio. Consequently, the required voltage for operating the memory can be reduced and overall operating efficiency of the memory cell can be increased. Moreover, the steps for fabricating the non-volatile memory in the present invention are simpler than the conventional process. Thus, overall production cost of the non-volatile memory is reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate having a device isolation structure thereon for defining an active region;
a second conductive type first well disposed in the substrate;
a first conductive type second well disposed on the second conductive type first well;
a plurality of second conductive type third wells disposed on the first conductive type second well and isolated from each other by the device isolation structure;
a plurality of bit lines disposed on the substrate;
a plurality of word lines disposed on the substrate and arranged to cross over the bit lines, wherein the cross points between each bit line and the word lines form a memory cell column, wherein the memory cell column comprising:
a plurality of first memory cells; and
a plurality of second memory cells;
a select unit disposed on one side of the memory cell column, wherein each of the first memory cells and the select unit are separated from one another by a gap respectively and the second memory cells are disposed within the gaps through a plurality of spacers;
a first conductive type first doped region disposed in the substrate just outside the select unit; and
a first conductive type second doped region disposed in the substrate on another side of the memory cell column, wherein the first conductive type second doped region and the second conductive type third well are electrically short-circuited together and electrically connected to a corresponding one of the bit lines.

2. The non-volatile memory of claim 1, wherein the first doped region is source region and the second doped is drain region.

3. The non-volatile memory of claim 1, wherein each first memory cell comprises a first charge-trapping layer and a first gate sequentially formed on the substrate and each second memory cell comprises a second charge-trapping layer and a second gate sequentially formed on the substrate.

4. The non-volatile memory of claim 3, wherein
each first memory cell further comprising:
a first bottom dielectric layer disposed between the first charge-trapping layer and the substrate;
a first top dielectric layer disposed between the first charge-trapping layer and the first gate;
each second memory cell further comprising:
a second bottom dielectric layer disposed between the second charge-trapping layer and the substrate;
a second top dielectric layer disposed between the second charge-trapping layer and the second gate; and
the select unit further comprising:
a third bottom dielectric layer, a third charge-trapping layer, a third top dielectric layer and a third gate sequentially formed on the substrate.

5. The non-volatile memory of claim 4, wherein the material constituting the first charge-trapping layer, the second charge-trapping layer and the third charge-trapping layer comprises silicon nitride or doped polysilicon.

6. The non-volatile memory of claim 4, wherein the material constituting the first bottom dielectric layer, the first top dielectric layer, the second bottom dielectric layer, the second top dielectric layer, the third bottom dielectric layer and the third top dielectric layer comprises silicon oxide.

7. The non-volatile memory of claim 1, wherein the first conductive type is n-type and the second conductive type is p-type.

8. The non-volatile memory of claim 1, wherein the memory further comprising:
an inter-layer insulating layer disposed on the substrate; and
a plurality of conductive plugs disposed in the inter-layer insulating layer for connecting the first conductive type drain regions to their corresponding bit lines respectively.

9. The non-volatile memory of claim 1, wherein the spacers are disposed on the sidewalls of the first memory cells and the select unit respectively.

10. A non-volatile memory, comprising:
a substrate having a device isolation structure thereon for defining an active region;
a second conductive type first well disposed on the substrate;
a first conductive type second well disposed in the second conductive type first well;
a plurality of second conductive type third wells disposed on the first conductive type second well and isolated from each other by the device isolation structure;
a plurality of memory cell columns arranged to form an array and disposed on the second conductive type third well, wherein each memory cell column having:
a plurality of serially connected memory cells isolated from each other by first insulating spacers;
a select unit connected to the outermost memory cell of the serially connected memory cells through a second insulating spacer;
a first conductive type source region disposed in the substrate just outside the select unit;
a first conductive type drain region disposed in the substrate on the other side of the serially connected memory cells;
a plurality of select lines connected to gates of the select units in the same row;
a plurality of word lines arranged in parallel in the row direction and connected to gates of the memory cells in the same row;
a plurality of source lines connected to the first conductive type source regions in the same row; and
a plurality of bit lines arranged in parallel in the column direction with each bit line connected to the first conductive type drains in the same column through a conductive plug, wherein each conductive plug penetrates through the junction between the first conductive type drain region and the second conductive type third well so that the first conductive type drain and the second conductive type third well are short-circuited together.

11. The non-volatile memory of claim 10, wherein the memory cells in the same memory cell column are grouped in pairs to form a plurality of memory units from the first conductive type drain region side to the first conductive type source region side such that in each pair the memory cell close to the first conductive type drain region is named a first memory cell and the memory cell closed to the first conductive type source region is named a second memory cell, and
the first memory cell, including:
a first gate disposed on the substrate;
a first composite layer disposed between the first gate and the substrate, wherein the composite layer comprises a first bottom dielectric layer, a first charge-trapping layer and a first top dielectric layer sequentially formed on the substrate; and
the second memory cell disposed on one sidewall of the first memory cell and the substrate, including:
a second gate disposed on the substrate;
a second composite layer disposed between the second gate and the substrate and between the second gate and the first memory cell, wherein the second composite layer comprises a second bottom dielectric layer, a second charge-trapping layer and a second top dielectric layer sequentially formed on the substrate and the sidewall on one side of the first memory cell;
wherein the first insulating spacers are disposed on the sidewalls of the first memory cell.

12. The non-volatile memory of claim 11, wherein the material constituting the first charge-trapping layer and the second charge-trapping layer comprises silicon nitride or doped polysilicon.

13. The non-volatile memory of claim 11, wherein the material constituting the first bottom dielectric layer, the first top dielectric layer, the second bottom dielectric layer and the second top dielectric layer comprises silicon oxide.

14. The non-volatile memory of claim 10, wherein each select unit comprising:
a third gate disposed on the substrate;
a third composite layer disposed between the third gate and the substrate, wherein the third composite layer comprises a third bottom dielectric layer, a third charge-trapping layer and a third top dielectric layer sequentially formed on the substrate; and
a third insulating spacer disposed on the sidewall of the third gate and the third composite layer.

15. The non-volatile memory of claim 14, wherein the material constituting the third charge-trapping layer comprises silicon nitride or doped polysilicon.

16. The non-volatile memory of claim 14, wherein the material constituting the third bottom dielectric layer and the third top dielectric layer comprises silicon oxide.

17. The non-volatile memory of claim 10, wherein the first conductive type is n-type and the second conductive type is p-type.

18. A method of operating a non-volatile memory, in particular, a memory cell array, wherein the memory cell array comprises: a substrate having a device isolation structure thereon for defining an active region; a second conductive type first well disposed in the substrate; a first conductive type second well disposed in the second conductive type first well; a plurality of second conductive type third wells disposed on the first conductive type second well and isolated from each other by the device isolation structure; a plurality of memory cell columns arranged to form a the memory cell array disposed on the second conductive type third well such that each memory cell column comprises: a plurality of memory cells each having at least a charge-trapping layer and the memory cells serially connected together through spacers without any gaps in-between, a select unit connected to the memory cell on one side of the serially connected memory cells, a first conductive type source region disposed in the substrate just outside the select unit, a first conductive type drain region disposed in the substrate on one the other side of the serially connected memory cells; a plurality of select lines connected to gates of the select units on the same row; a plurality of word lines arranged in parallel in the row direction and connected to gates of the memory cells in the same row respectively; a plurality of source lines connected to the first conductive type source regions on the same row; a plurality of bit lines arranged in parallel in the column direction and connected to the first conductive type drain regions on the same column through a conductive plug such that the conductive plug penetrate through the junction between the first conductive type drain region and the second conductive type third well so that the first conductive type drain region and the second conductive type third well are short-circuited together, the method comprising the steps of:
performing an erasing operation by applying a first voltage to the word lines, applying a second voltage to the first conductive type source lines and the second conductive type third well, applying a third voltage to the select line, the first conductive type second well, the second conductive type first well, setting the bit lines to a floating state, wherein the voltage differential between the first voltage and the second voltage is sufficient to make electrons inject into the charge-trapping layer by FN tunneling to erase the memory cell array.

19. The method of claim 18, wherein the first voltage is about 6V, the second voltage is about −6V and the third voltage is about 0V.

20. The method of claim 18, wherein the method further comprising:
performing a programming operation by applying a fourth voltage to a selected bit line so that the fourth voltage is also applied to the second conductive type third well, applying a fifth voltage to a selected source line, applying a sixth voltage to a word line that couples with a selected memory cell and applying a seventh voltage to other word lines that couple with non-selected memory cells and the corresponding select line and applying an eighth voltage to the first conductive type second well, wherein the voltage differential between the fourth voltage and the sixth voltage is sufficient to pull electrons out of the charge-trapping layer by FN tunneling to program the selected memory cell.

21. The method of claim 20, wherein the fourth voltage is about 3.3V, the fifth voltage is about 3.3V, the sixth voltage is about −9V, the seventh voltage is about 0V and the eighth voltage is about 3.3V.

22. The method of claim 18, wherein the method further comprising:
performing a reading operation by applying a 0V to a selected bit line, applying a ninth voltage to a word line that couples with a selected memory cell and applying a tenth voltage to the non-selected word lines and the corresponding select line, applying an eleventh voltage to the source line, wherein the tenth voltage is sufficient to turn on the channel of the memory cells and the select unit and the ninth voltage is lower than the threshold voltage of the memory cells in erasing state but higher than the threshold voltage of the memory cells in programming state so that data can be read from the selected memory cell.

23. The operating method of claim 22, wherein the ninth voltage is about 1.5V, the tenth voltage is about 6V and the eleventh voltage is about 1.5V.

24. A method of fabricating a non-volatile memory, comprising the steps of:
providing a substrate having a device isolation structure thereon for defining an active region;
forming a second conductive type first well in the substrate;
forming a first conductive type second well on the second conductive type first well;
forming a plurality of second conductive type third wells on the first conductive type second well, wherein the second conductive type third wells are isolated from each other by the device isolation structure;
forming a plurality of stacked gate structures on the substrate, wherein each stacked gate structure comprises a first composite layer, a first gate and a cap layer and there is a gap between two adjacent stacked gate structures;
forming a plurality of insulating spacers on the sidewalls of the stacked gate structures;
forming a second composite layer over the substrate;
forming a conductive layer over the substrate;
removing a portion of the conductive layer to form a plurality of second gates that completely fill the gaps between the stacked gate structures, wherein the second gates and the stacked gate structures together form a memory cell column;
forming a first conductive type source region and a first conductive type drain region in the substrate on the sides of the memory cell column respectively;
forming a first inter-layer insulating layer on the substrate;
forming a source line in the first inter-layer insulating layer, wherein the source line connects with the first conductive type source region;
forming a second inter-layer insulating layer on the first inter-layer insulating layer;
forming a conductive plug in the second inter-layer insulating layer, wherein the conductive plug penetrates through the junction between the first conductive type drain region and the second conductive type third well so that the first conductive type drain region and the second conductive type third well are short-circuited together; and
forming a bit line on the second inter-layer insulating layer, wherein the bit line connects with the conductive plug.

25. The method of claim 24, wherein the first composite layer and the second composite layer each comprises a bottom dielectric layer, a charge-trapping layer and a top dielectric layer.

26. The method of claim 24, wherein the step of removing a portion of the conductive layer comprises performing a chemical-mechanical polishing operation.

27. The method of claim 24, wherein the step of forming the first conductive type source region and the first conductive type drain region in the substrate comprises performing an ion implantation.

28. The method of claim 24, wherein the step of forming the insulating spacers on the sidewalls of the stacked gate structures comprising:
depositing insulating material over the substrate to form an insulating layer; and
performing a self-aligned anisotropic etching operation to remove a portion of the insulating layer.

29. The method of claim 22, wherein the first conductive type is n-type and the second conductive type is p-type.

30. The method of claim 23, wherein the material constituting the charge-trapping layer comprises silicon nitride or doped polysilicon.

31. The method of claim 23, wherein the material constituting the bottom dielectric layer and the top dielectric layer comprises silicon oxide.

32. The method of claim 22, wherein the material constituting the first gate and the second gate comprises doped polysilicon.
